(19) United States
(12) Patent Application Publication
(10) Pub. No.: US 2009/0007036 A1
(43) Pub. Date: Jan. 1, 2009

(54) Integrated Fin-Local Interconnect Structure

(75) Inventors: Kangguo Cheng, Guilderland, NY (US); Louis Lu-Chen Hsu, Fishkill, NY (US); Jack Allan Mandelman, Flat Rock, NC (US); William Robert Tonti, Essex Junction, VT (US)

Correspondence Address: IBM CORPORATION, INTELLECTUAL PROPERTY LAW;DEPT 917, BLDG. 006-1, 3605 HIGHWAY 52 NORTH, ROCHESTER, MN, 55901-7829, US

(73) Assignee: INTERNATIONAL BUSINESS MACHINES CORPORATION, Armonk, NY (US)

(21) Appl. No.: 11/925,387

(22) Filed: Oct. 26, 2007

Related U.S. Application Data
(63) Continuation-in-part of application No. 11/770,783, filed on Jun. 29, 2007.

(51) Int. Cl. G06F 9/45

(52) U.S. Cl. 716/5

(57) ABSTRACT

Embodiments of the invention generally relate to methods, systems and design structures for semiconductor devices, and more specifically to interconnecting semiconductor devices. A silicide layer may be formed on selective areas of a fin structure connecting one or more semiconductor devices or semiconductor device components. By providing silicided fin structures to locally interconnect semiconductor devices, the use of metal contacts and metal layers may be obviated, thereby allowing formation of smaller, less complex circuits.

### CROSS-REFERENCE TO RELATED APPLICATIONS

This application is a continuation-in-part of co-pending U.S. patent application Ser. No. 11/770,783, filed Jun. 29, 2007, which is herein incorporated by reference.

### BACKGROUND OF THE INVENTION

1. Field of the Invention

The present invention generally relates to methods, systems and design structures for semiconductor devices, and more specifically to interconnecting semiconductor devices.

2. Description of the Related Art

Over the past few decades, the speed and density of transistors in integrated circuits has continued to increase in accordance with Moore's law, which predicts exponential growth. Consequently, integrated circuits such as microprocessors have delivered greater functionality and performance at a lower cost. As devices on integrated circuits, for example, transistors have become smaller, faster, and cheaper, the use of integrated circuits has become more widespread. Furthermore, the demand for better, faster, cheaper, and improved integrated circuits continues to grow. As a result, innovative technologies for constructing faster and smaller transistors continue to be developed and adopted.

Fin Field Effect Transistor (FinFET) technology is one such innovative approach used to construct high performance, densely packed transistors on integrated circuits. A FinFET is a double gate structure that is easily manufactured using current fabrication techniques. In a FinFET, a vertical fin is defined to form the body of a transistor. Gates can be formed on one or both sides of the vertical fin. When both sides of the vertical fin have a gate formed thereon, the transistor is generally referred to as a double-gate FinFET. A double-gate FinFET helps suppress short channel effects (SCE), reduce leakage, and enhance switching behavior. Also, a double gate FinFET can increase the electrical width of the transistor, which can in turn increase on-current without increasing the length of the gate conductor.

FIG. 1 illustrates an exemplary FinFET transistor 1 00. FinFET transistor 100 is shown as a Complementary Metal-Oxide Semiconductor (CMOS) transistor in FIG. 1. A CMOS transistor includes complementary and symmetric n-type and p-type Metal Oxide Semiconductor Field Effect Transistors (MOSFETS). For example, FinFET 100 may include a p-type MOSFET comprising a source region 110 and a drain region 120 connected by a fin structure 130. FinFET 100 may also include an n-type MOSFET comprising a source region 140. The drain region 120 of the p-type MOSFET is shared with the n-type MOSFET, as illustrated in FIG. 1. A fin structure 150 may connect the drain region 120 to the source region 140 of the n-type MOSFET.

A gate structure 160 is formed over each of the fin structures 130 and 150 as shown in FIG. 1. One or more contacts may be landed on each of the source regions 110 and 140, drain region 120, and gate structure 160. For example, in FIG. 1, contacts 111 and 112 are formed in source region 110, contacts 141 and 142 are formed in the source region 140, contact 121 is formed in drain region 120, and contact 161 is formed on the gate structure 160. The contacts may be provided to electrically couple the FinFET 100 components or to connect FinFET 100 to other semiconductor devices, for example, other FinFETs.

As illustrated in FIG. 1, source regions 110 and 140, and drain region 120 must be sufficiently large to accommodate the contacts. For example, source region 110 must be sufficiently large so that contacts 111 and 112 are contained within the source region. Accommodation of the contacts within the drain and source regions is necessary to prevent the contacts from electrically coupling with structures such as, for example, the fin structures, which may adversely affect the performance of FinFET 100. However, accommodating the contacts may require formation of large source and drain regions which may limit the scalability of semiconductor devices. In other words, the large source and drain regions may limit the ability to build smaller, faster, and cheaper transistors.

Furthermore, each contact is typically coupled with a metal layer to connect a semiconductor device to other devices. For example, contacts 111 and 112 may be coupled with a metal layer 171, contacts 141 and 142 may be coupled with a metal layer 172, and contact 121 may be coupled with a metal layer 173. Metal layers 171, 172, and 173 may be associated with signals V_{DD}, V_{SS}, and Vₒᵤₜ respectively, as illustrated in FIG. 1. However, including metal layers and contacts consume valuable space on the integrated circuit and greatly increase circuit complexity, particularly when a large number of devices must be interconnected.

Accordingly, what is needed are improved methods, systems and articles of manufacture for interconnecting semiconductor devices.

### SUMMARY OF THE INVENTION

The present invention generally relates to semiconductor devices, and more specifically to interconnecting semiconductor devices.

One embodiment of the invention provides a transistor, generally comprising a source region, a drain region, and a channel region coupled with the source region and the drain region. At least one of the source region and the drain region is a semiconductor fin structure, wherein at least a portion of the fin structure comprises a silicide material, the portion of the fin structure comprising the silicide material being configured to electrically couple one of the respective source region and drain region of the transistor with an associated circuit component of an electric circuit.

Another embodiment of the invention provides a method for connecting components of an electrical circuit. The method generally comprises forming a fin structure coupled with a first circuit component and at least one second circuit component of the electrical circuit, masking one or more areas of the electrical circuit wherein formation of silicide material is not desired, and forming a silicide layer on at least a portion of the fin structure, wherein the silicide material is configured to electrically connect the first circuit component to the at least one second circuit component.

Yet another embodiment of the invention provides an electrical circuit, generally comprising a first circuit component, a second circuit component, and a fin structure coupled with the first circuit component and the second circuit component. At least a portion of the semiconductor fin structure comprises a silicide material, wherein the portion of the semiconductor fin structure comprising the silicide material being configured to electrically connect the first circuit component to the second circuit component.

Yet another embodiment of the invention provides a design structure embodied in a machine readable medium for at least one of designing, manufacturing, and testing a design. The design structure generally includes a transistor, generally having a source region, a drain region, and a channel region coupled with the source region and the drain region. At least one of the source region and the drain region is a semiconductor fin structure, wherein at least a portion of the fin structure comprises a silicide material, the portion of the fin structure comprising the silicide material being configured to electrically couple one of the respective source region and drain region of the transistor with an associated circuit component of an electric circuit.

Yet another embodiment of the invention provides a design structure embodied in a machine readable medium for at least one of designing, manufacturing, and testing a design where the design structure generally includes an electrical circuit, generally having a first circuit component, a second circuit component, and a fin structure coupled with the first circuit component and the second circuit component. At least a portion of the semiconductor fin structure comprises a silicide material, wherein the portion of the semiconductor fin structure comprising the silicide material being configured to electrically connect the first circuit component to the second circuit component.

### BRIEF DESCRIPTION OF THE DRAWINGS

So that the manner in which the above recited features, advantages and objects of the present invention are attained and can be understood in detail, a more particular description of the invention, briefly summarized above, may be had by reference to the embodiments thereof which are illustrated in the appended drawings.

It is to be noted, however, that the appended drawings illustrate only typical embodiments of this invention and are therefore not to be considered limiting of its scope, for the invention may admit to other equally effective embodiments.

FIG. 1 illustrates an exemplary CMOS device according to the prior art.

FIG. 2 illustrates an exemplary CMOS device according to an embodiment of the invention.

FIG. 3 illustrates a cross sectional view of an exemplary interconnect structure according to an embodiment of the invention.

FIG. 4 illustrates a cross sectional view of another exemplary interconnect structure according to an embodiment of the invention.

FIG. 5 illustrates a cross sectional view of yet another exemplary interconnect structure according to an embodiment of the invention.

FIG. 6 illustrates an exemplary masked gate structure according to an embodiment of the invention.

FIG. 7 is a flow diagram of exemplary operations performed to create a silicided interconnect structure, according to an embodiment of the invention.

FIG. 8 illustrates an exemplary current type digital to analog circuit (IDAC) according to an embodiment of the invention.

FIG. 9 illustrates an exemplary layout for the IDAC circuit illustrated in FIG. 8, according to an embodiment of the invention.

FIG. 10 illustrates an intersection between two fin structures according to an embodiment of the invention.

FIG. 11 illustrates another exemplary layout for the IDAC circuit illustrated in FIG. 8, according to an embodiment of the invention.

FIG. 12 is a flow diagram of a design process used in semiconductor design, manufacturing, and/or test.

### DETAILED DESCRIPTION OF THE PREFERRED EMBODIMENTS

The present invention generally relates to semiconductor devices, and more specifically to interconnecting semiconductor devices. A silicide layer may be formed on selective areas of a fin structure connecting one or more devices or device components. By providing silicided fin structures to locally interconnect devices, the use of metal contacts and metal layers may be obviated, thereby allowing formation of smaller and less complex circuits.

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, in various embodiments the invention provides numerous advantages over the prior art. However, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

### Exemplary Local Interconnect Structures

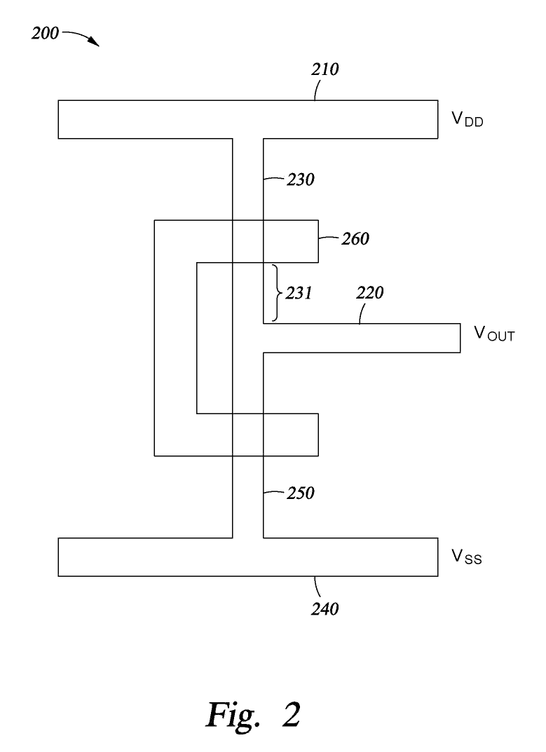

FIG. 2 illustrates an exemplary FinFET device 200, according to an embodiment of the invention. As illustrated in FIG. 2, FinFET device 200 may be a CMOS transistor. Accordingly, FinFET 200 may include source regions 210 and 230 and a common drain region 220. A fin structure 230 may couple the source region 210 with the drain region 220, and a fin structure 250 may couple the source region 240 with the drain region 220, as illustrated in FIG. 2. Furthermore, as shown in FIG. 2, a gate structure 260 may be formed over the fin structures 230 and 250.

Gate structure 260 may be disposed along at least one face of the fin structures 230 and 250. For example, the gate structure may be disposed along the three faces, i.e., the top face and the side faces of fin structure 230. It is noteworthy that the gate structure 260 may be disposed on any number of faces of fin structure 230. For example, gate structure 260 may surround ails faces of fin structure 230 or, alternatively, in some embodiments, gate structure 260 may be disposed on the two side faces of fin structure 230.

In one embodiment of the invention, gate structure 260 may be made from one of polysilicon or amorphous silicon. Gate structure 260 may be formed by a suitable process known in the art, for example, Low Pressure Chemical Vapor Deposition (LPCVD).

The narrowness of fin structure 230 and the gating of fin structure 230 with gate structure 260 on at least two faces of fin structure 110 may provide greatly reduced short channel sensitivity and improved scalability of channel length. Furthermore, gate structure 260 may maintain a strong control of semiconductor potential and may screen a transistor source from penetrating into a transistor drain electric field. Such strong gate control may enable near ideal sub-threshold (Vt) swing, as well as reduced sensitivity of threshold (Vt) to drain voltage and channel length variations.

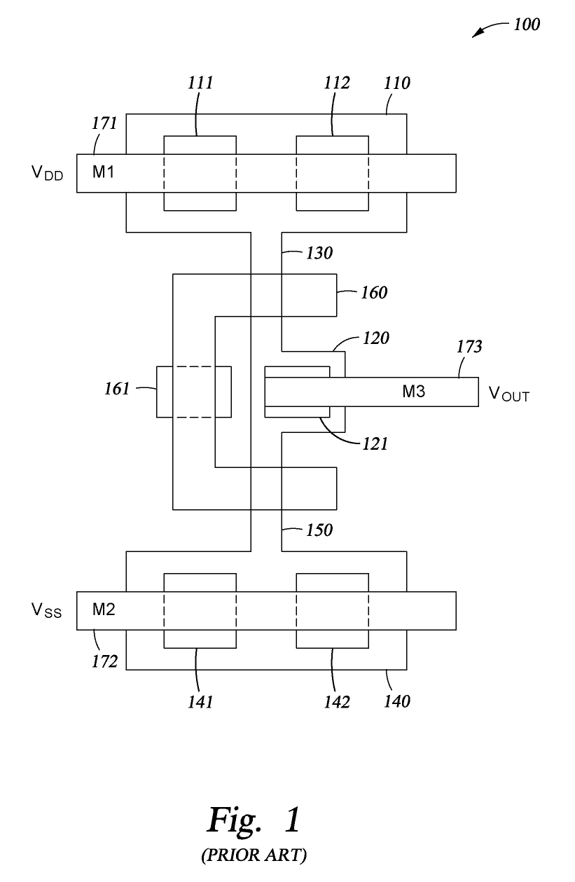

Source regions 210 and 240, and drain region 220 in FIG. 2 may be formed in a significantly smaller area in comparison to the source regions 110 and 130, and drain region 120 respectively in FIG. 1. The source and drain regions illustrated in FIG. 2 may be smaller than the corresponding source and drain regions illustrated in FIG. 1 because the contacts 111, 112, 121, 141, and 142 are not included in the embodiment illustrated in FIG. 2. Instead of including contacts, embodiments of the invention provide local interconnect structures that obviate the need for contacts and metal layers to interconnect semiconductor devices and semiconductor device components. The local interconnect structures may be formed by selective silicidation of one or more of the drain region, source region, and fin structures to provide local interconnects. By obviating the need for contacts and metal layers, embodiments of the invention allow the formation of smaller semiconductor devices and reduce complexity of circuits.

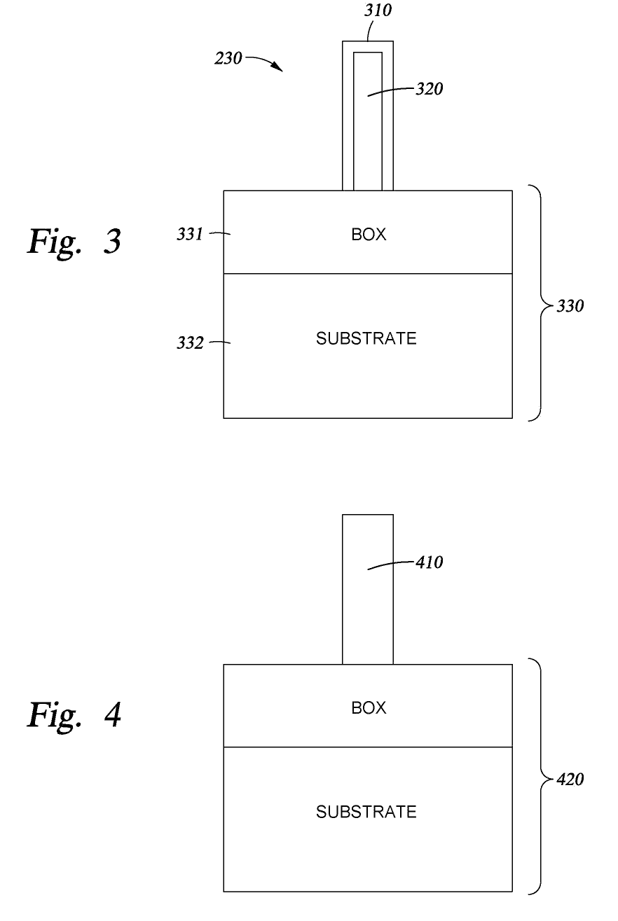

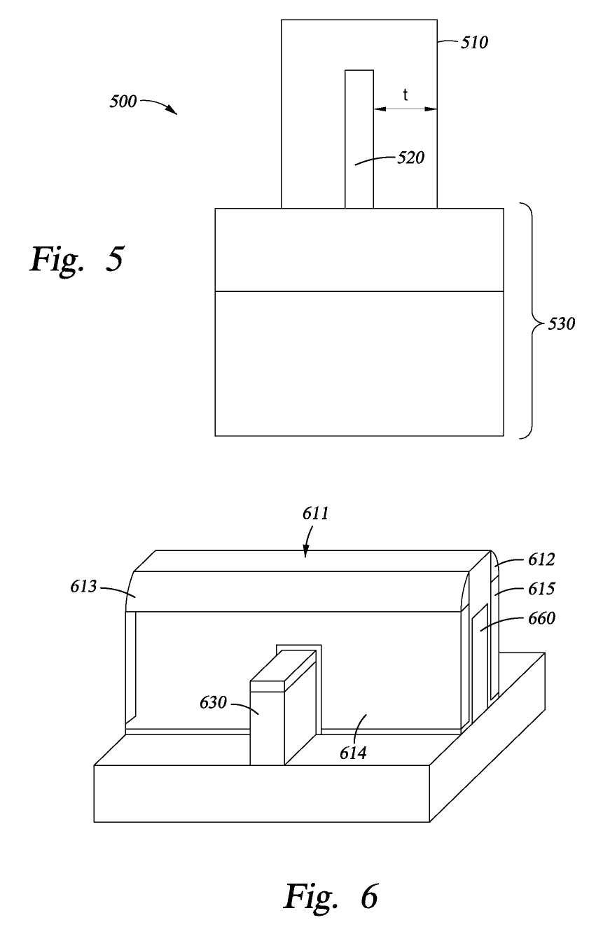

In one embodiment of the invention, the source regions, for example source regions 210 and 240 in FIG. 2, and drain regions, for example, drain region 220 in FIG. 2, may be formed as fin structures. In other words, at least a portion of a semiconductor fin structure may be formed with a predetermined amount of dopant to create the source and drain regions. Connecting the source and drain regions to other components or devices such as, for example, other transistors may involve forming a silicide cladding layer on the fin source and drain structures, such as the silicide cladding layers described with reference to FIGS. 3 and 5 below. The fin structure forming the source region and drain region may extend and couple with another circuit component or device and the silicide cladding layer may electrically couple the drain or source regions of the FinFET to the other component or device.

While a CMOS FinFET transistor structure is described herein to illustrate the use of local interconnect structures, one skilled in the art will recognize that embodiments of the invention may be used to provide local interconnects for any semiconductor device for example, n-type MOSFETs, p-type MOSFETS, pn junctions, bipolar transistors, and the like.

In one embodiment of the invention, it may be necessary to interconnect one or more components of a semiconductor device. For example, in a depletion mode MOSFET, it may be necessary to connect a drain region of the depletion mode MOSFET to the gate structure of the depletion mode MOSFET. Accordingly, a silicide layer may be formed on the drain region and a fin structure connecting the source region to the gate structure. For example, referring to FIG. 2, a silicide layer may be formed on the drain region 220 and a portion 231 of the fin structure 230 to connect the drain region 220 to the gate structure 260.

FIG. 3 illustrates a cross section of a silicided portion of fin structure 230 according to one embodiment of the invention. As illustrated in FIG. 3, fin structure 230 may be formed on a substrate 330. In one embodiment of the invention substrate 330 may be a bulk silicon substrate. Accordingly, substrate 330 may be made from any suitable semiconductor material, for example, Silicon, Germanium, Silicon Germanium, Gallium Arsenic, Indium Phosphorus, and the like.

Alternatively, substrate 330 may be a Silicon-On-Insulator (SOI) substrate including an insulator layer 331 disposed on a semiconductor layer 332. FIG. 3 illustrates an exemplary SOI substrate 330 according to an embodiment of the invention. SOI substrate 330 may include an insulator layer 331 formed on a semiconductor layer 332. Semiconductor layer 332 may be made from a suitable semiconductor material, for example, Silicon, Germanium, Silicon Germanium, Gallium Arsenic, Indium Phosphorus, and the like. As illustrated in FIG. 3, insulator layer 331 may be disposed on and adjacent to the semiconductor layer 331. In one embodiment of the invention, insulator layer 331 may be a Buried Oxide (BOX) layer.

The fin structure 230 may be formed on the insulator layer 331, as illustrated in FIG. 3. In one embodiment of the invention, fin structure 230 may include a core region 320 and a silicide cladding layer 310, as illustrated in FIG. 3. The core region 320 may be formed with any suitable semiconductor material, for example, Silicon, Germanium, Silicon Germanium, Gallium Arsenic, Indium Phosphorus, and the like. A part or entire portion of the core region 320 may be strained. The core region 320 may or may not be made from the same semiconductor material as the semiconductor layer 332.

Silicide cladding layer 310 may be formed with a semiconductor material and one or more electropositive elements. For example, in one embodiment, silicide cladding layer may be formed with silicon and one or more metals. Exemplary metals used to form the silicide cladding layer 310 may include tungsten, tantalum, cobalt, nickel, titanium, and the like. Silicide cladding layer 310 may be highly conductive. For example, in one embodiment, the silicide cladding layer 310 may be more conductive than polysilicon. Therefore, the silicide cladding layer 310 may electrically connect one or more components of a semiconductor device. For example, referring back to FIG. 2, a silicide layer formed on the drain region 220 and the fin structure 230 may electrically couple the source region 210 to the gate structure 260 to form a depletion mode MOSFET.

Another advantage of using a silicide layer 310 to interconnect semiconductor device components may be that a silicide layer is capable of withstanding greater temperatures than metal interconnects while providing low resistance connections.

One reason for including a core region 320 may be to reduce the contact resistance due to the transition from a silicided interconnect region, for example, a silicided cladding layer 310, to a device component, for example, a transistor drain or source. The contact resistance from a silicided interconnect region to a device component may depend on the surface area at the interface of the silicided and unsilicided regions. By providing an unsilicided core, the surface area at the interface of silicided and unsilicided regions may be greatly increased, thereby reducing contact resistance.

In one embodiment of the invention, fin structure 230 may be fully silicided. In other words, a core region 320 may not be provided. FIG. 4 illustrates a fin structure 410 formed on a SOI substrate 420. SOI substrate 420 may be similar to the SOI substrate 330 illustrated in FIG. 3. As illustrated in FIG. 4, the fin structure 410 may be fully silicided, without a semiconductor core region. One advantage of using a fully silicided fin structure 410 may be that the series resistance of the interconnect region may be greatly reduced.

For example, the series resistance of the silicided interconnect may depend on the cross sectional area of the fully silicided core 410. In other words, because electrons may flow in a direction normal to the cross sectional area of the silicided region 410 illustrated in FIG. 4, a greater cross sectional area may result in a lower series resistance for the silicided interconnect. A fully silicided fin structure may increase the cross sectional area of the silicided core to achieve a lower series resistance.

FIG. 5 illustrates an embodiment of the invention that achieves both, a lower contact resistance, and a lower series resistance. As illustrated in FIG. 5, a fin structure 500 may be formed on a substrate 530. Substrate 530 may be similar to the substrate 330 described above with reference to FIG. 3. Fin structure 500 may include a semiconductor core region 520 and a thick nitride cladding layer 510.

Semiconductor core region 520 may be similar to the semiconductor core region 320 illustrated in FIG. 3, and may be formed with a suitable semiconductor material, for example, Silicon, Germanium, Silicon Germanium, Gallium Arsenic, Indium Phosphorus, and the like. Semiconductor core region 520 may be provided to increase the surface area at the interface of silicided and unsilicided regions of the fin structure 500, thereby reducing contact resistance.

A relatively thick silicide cladding layer 510 may be provided to reduce series resistance. The thickness t of the silicide cladding layer may be sufficiently large to achieve a desired low series resistance value. Therefore, in the embodiment illustrated in FIG. 5, the semiconductor core region 520 may provide a lower contact resistance value and the thick silicide layer 510 may provide a low series resistance value for the interconnect.

### Methods for Forming a Silicide Interconnect

Forming a silicide interconnect may begin by first forming one or more other structures of a semiconductor device. For example, a source region, a drain region, a fin structure connecting the source and drain regions, and a gate structure of a transistor may first be formed before forming silicide interconnects. In one embodiment of the invention, one or more regions of the semiconductor device may be masked selectively to form the silicide interconnects in particular desired areas. For example, the gate structure of a transistor may be masked to prevent formation of silicide on the gate structure.

FIG. 6 illustrates exemplary masking of a gate structure, according to an embodiment of the invention. FIG. 6 illustrates a fin structure 630 and a gate structure 660 formed thereon. As illustrated in FIG. 6, the gate structure may be completely encapsulated to prevent formation of silicide on the gate structure. For example, gate structure 660 may be encapsulated with a cap layer 611, cap spacers 612 and 613, and sidewall spacers 614 and 615. In one embodiment of the invention the cap layer 611 and the cap spacers 612 and 613 may be formed with a suitable nitride material, for example, silicon nitride. In one embodiment, the sidewall spacers may be made from a dielectric material. The method for encapsulating the gate structure 660 is described in greater detail in co-pending U.S. patent application Ser. No. 11/225,654 titled SEMICONDUCTOR FINFET STRUCTURES WITH ENCAPSULATED GATE ELECTRODES AND METHODS FOR FORMING SUCH SEMICONDUCTOR FINFET STRUCTURES, filed Sep. 13, 2005 by Hsu et al. The aforementioned patent application is incorporated herein by reference in its entirety.

In one embodiment of the invention, a nitride layer may be formed on the top of the fin structure 630 as illustrated in FIG. 6. Therefore, forming the silicide interconnect may proceed along the sidewall portions of the fin structure. Alternatively, the nitride layer formed on the fin structure 630 may be removed using a nitride selective etch prior to silicidation. The nitride layer on the fin structure 630 may be substantially thinner than the nitride layer on the gate structure. Therefore, in one embodiment, the nitride layer over the fin structure 630 may be removed by a controlled nitride selective etch without completely removing the nitride cap 611 and cap spacers 612 and 613. Alternatively, a mask may be used to prevent etching of the nitride cap 611 and cap spacers 612 and 613 during etching of the nitride layer over the fin structure 630.

Silicidation of an exposed fin structure may begin by depositing a layer of metal over the exposed fin structure. Exemplary metals may include, for example, tungsten, tantalum, cobalt, nickel, titanium, and the like. Following deposition of metal on the exposed fin structure, an annealing procedure may be performed to incorporate the deposited metal in the fin structure to form a silicide layer on the fin structure. Annealing may be performed in a furnace under predetermined temperatures for a predetermined amount of time. Alternatively, LASER annealing, rapid thermal processing, and like annealing procedures may also be used.

In one embodiment of the invention, the annealing procedure may result in the formation of the silicide cladding layer 310 illustrated in FIG. 3. If a fully silicided fin structure is desired, a high dose of metal may be deposited on the fin structure, followed by a more aggressive annealing procedure to allow the metal to be fully incorporated into the fin structure. For example, the annealing may involve greater temperatures and a greater duration in an annealing furnace to allow metals to be incorporated completely into the fin structure.

A selective metal etch may be performed after the annealing procedure to remove excess unreacted metal that may be left over on the surface of the fin. In one embodiment, the metal etch may be performed via wet etch procedures using, for example, a mixture comprised of H2SO4-H2O2-HCl-NHOH4-H3PO4-HNO3-CH3COOH.sup.-, and the like. In some embodiments, a second annealing procedure may be performed after removal of the unreacted metal to lower the silicide resistance.

In one embodiment of the invention, additional silicide material may be deposited on the fin structure to form a thick silicide cladding layer. For example, the annealing procedure described above may be used to form a silicide cladding layer 310 in a fin structure. Following formation of the silicide cladding layer additional silicide material may be deposited on the fin structure to form a thick silicide layer 510, as illustrated in FIG. 5. Any reasonable method, for example, epitaxial growth, chemical vapor deposition (CVD), low pressure chemical vapor deposition (LPCVD), and the like may be used to form the thick silicide cladding layer.

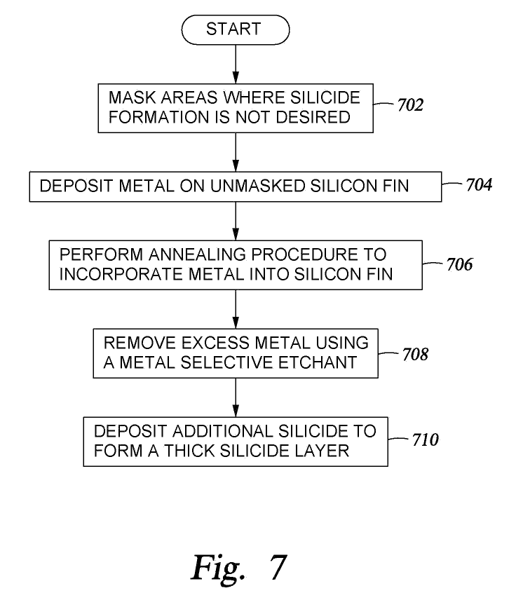

FIG. 7 is a flow diagram of exemplary operations that may be performed to form silicide interconnects. The operations begin in step 702 by masking one or more areas on which silicide formation is not desired. For example, in one embodiment, a gate structure of a transistor may be encapsulated in masking layers (e.g., an oxide layer, nitride layer, or the like) to prevent formation of silicide thereon. In step 704, metal may be deposited on an exposed silicon fin. As described above, exemplary metals may include for example, tungsten, tantalum, cobalt, nickel, titanium, and the like. The deposited metal may be incorporated into the silicon fin by performing an annealing procedure in step 706 to form a silicide cladding layer on the fin structure.

In step 708 a metal selective etch may be performed to remove unreacted metal. In step 710, additional silicide material may be disposed on the fin structure to form a thick silicide layer, such as, for example, a thick silicide layer 510 illustrated in FIG. 5. The additional silicide layer may be formed on the fin structure using epitaxial growth or using a suitable deposition method. In some embodiments, the silicide layer may be directly grown on the silicon fin using epitaxial growth without first depositing metal and performing an annealing procedure

### Exemplary System Using a Local Interconnect Structure

In some embodiments, the local interconnect structures described herein may be used to interconnect one or more components of one or more devices of a circuit. For example, in some embodiments, fin local interconnect structures may be used to connect circuit components such as for example, transistors, capacitors, resistors, inductors, and the like. In other embodiments, fin local interconnect structures may act as a bus line to carry one or more signals, such as for example, a power signal to one or more circuit components. By providing local interconnect structures that obviate the need for metal contacts and metal layers, embodiments of the invention allow smaller and cheaper integrated circuits to be built.

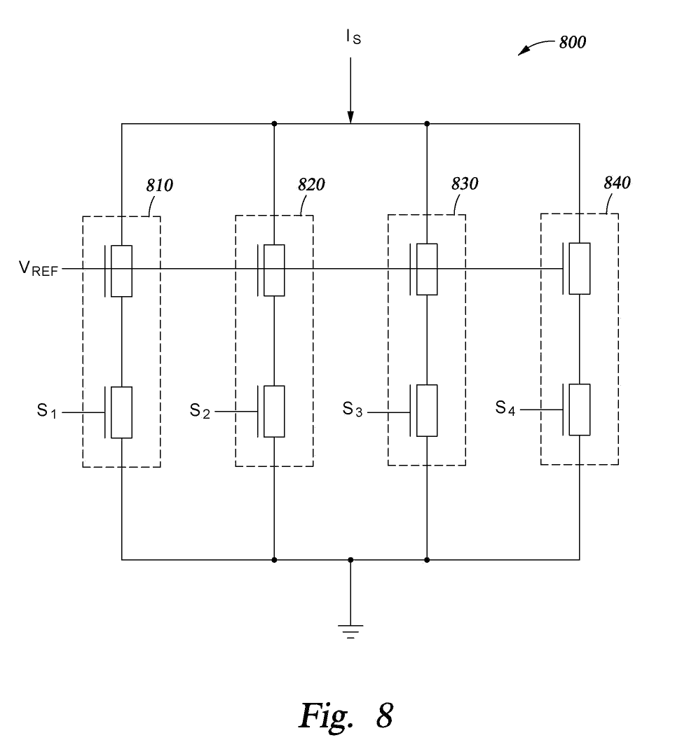

FIG. 8 illustrates an exemplary current-digital-to-analog circuit 800 (hereinafter referred to as an IDAC circuit). An IDAC circuit is commonly used in analog circuits to provide and control a source current (I_{S}) for components such as differential amplifiers, comparators, common mode logic, buffers, and the like. An IDAC circuit may receive a digital input value. In one embodiment, IDAC circuit may comprise a plurality of current mirror devices. For example, four current mirror devices 810-840 are illustrated in FIG. 8. Mirror devices 810-840 may consist of a plurality of transistors configured to generate a predetermined current output.

Each current mirror device 810-840 of IDAC circuit 800 may receive a digital input. For example, in FIG. 8, the digital input to each of the current mirror devices 810-840 is represented by bits S1-S4, respectively. Bits S1-S4 may be used to control the current I_{S} illustrated in FIG. 8. For example, bit S1 may be used to turn on device 810 that may allow a first current value to be generated. Similarly bit S2 may turn on device 820 that may allow a second current value to be generated, bit S3 may turn on device 830 that may allow a third current value to be generated, and bit S4 may turn on device 840 that may allow a fourth current value to be generated. Accordingly, bits S1-S4 may be used to generate one of 16 different values for current I_{S}.

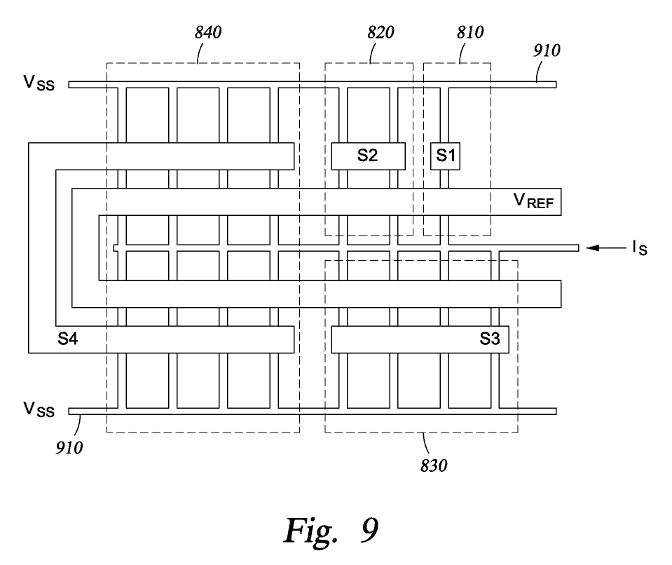

FIG. 9 illustrates an exemplary layout 900 for the IDAC circuit 800 illustrated in FIG. 8. As illustrated in FIG. 9, layout 900 may include a plurality of fin structures connected in a fishbone shape. In one embodiment, all crossing fins may be orthogonally shaped to tightly form the layout 900 in the smallest possible area. In one embodiment of the invention, forming substantially orthogonal fin structures may involve performing a crystallographic dependent etch configured to make rounded corners at the interface of crossing fin structures substantially orthogonal. For example, after forming semiconductor fin structures, a crystallographic dependent etch may be performed to form fin structures with substantially orthogonal corner regions.

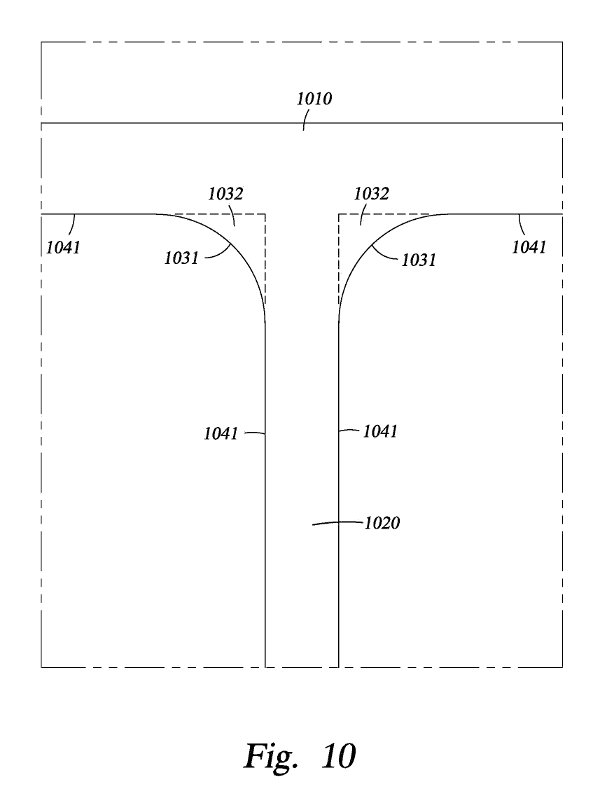

FIG. 10 illustrates the intersection between a first fin 1010 and a second fin 1020. As illustrated in FIG. 10, the intersection between fins 1010 and 1020 may form rounded corner regions 1031. A crystallographic dependent etch may etch away the semiconductor material 1032 at the corner regions 1031 at a much greater rate than the sidewall portions 1041 of the fin structure, thereby creating the substantially orthogonal corners. For example, the surface of the corner regions 1031 may be normal to a first crystallographic direction, and the sidewall portions 1041 may be normal to a second crystallographic direction. The crystallographic dependant etchant may remove semiconductor material normal to the first crystallographic direction at a much greater rate than the semiconductor material normal to the second crystallographic direction.

Exemplary crystallographic etchants may include, for example, Ammonium Hydroxide (NH₄OH), Potassium Hydroxide (KOH), Tetramethylammonium Hydroxide (TMAH), Hydrazine, Ethylene Diamine Pyrocatechol (EDP), and the like. Crystallographic dependent etching is dependent etching is described in greater detail in copending, commonly assigned U.S. patent application Ser. No. 11/680,221, Attorney Docket No. ROC920060072US1, entitled FINFET WITH REDUCED GATE TO FIN OVERLAY SENSITIVITY, filed Feb. 28, 2007, by Cheng et al. The aforementioned patent application is incorporated herein by reference in its entirety.

Referring back to FIG. 9, the current mirror devices 810-840 are identified in the layout design. As illustrated, current mirror device 810 may include a pair of transistors. The gate of a first transistor of the pair of transistors may be coupled to a voltage V_{ref}. In one embodiment, V_{ref} may be the reference voltage of a diode (not shown in FIG. 9) configured to allow current generated by the first mirror device 810 to be sourced to the current Iₛ. The gate of the second transistor of the pair of transistors may be coupled to the digital input S1, as illustrated in FIG. 9.

Current mirror device 820 may comprise two pairs of transistors similar to the pair of transistors in current mirror device 810, wherein, for each pair, the gate of the first transistor of the pair of transistors is couple with V_{ref}, and the gate of the second transistor of the pair of transistors is coupled with the digital input S2. Current mirror devices 830 and 840 may be similarly constructed, wherein current mirror device 830 comprises 4 pairs of transistors, and current mirror device 840 comprises 8 pairs of transistors, as illustrated in FIG. 9. A transistor in each pair of transistors in current mirror device 830 may receive the digital input S3, and a transistor in each pair of transistors in device 840 may receive the digital input S4.

Each pair of transistors may be connected using silicided local interconnect structures. For example, a portion of one or more fins illustrated in FIG. 9 may be silicided using the methods described above to create local silicided interconnects. Furthermore, silicided interconnects may be used to create a bus line for providing power to one or more circuit components. For example, a fin structure 910 may represent a Vₛₛ bus configured to provide power to the transistors in devices 810-840. Similarly a fin structure 920 may provide a bus for receiving the current Iₛ.

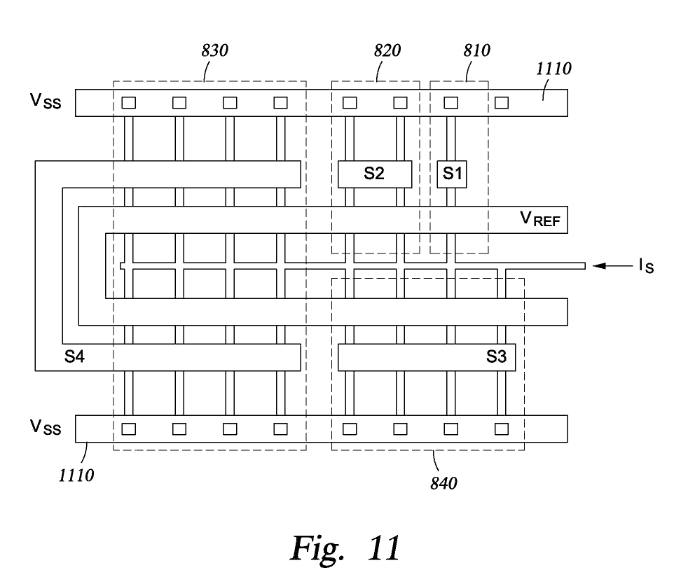

While an IDAC circuit is disclosed herein for illustrative purposes, one skilled in the art will recognize that embodiments of the invention may be implemented in any semiconductor circuit. Furthermore, any combination of silicided and unsilicided interconnects may be implemented. For example, in one embodiment, the Vss buses 910 may be formed with metal contacts and metal layers 1110, as illustrated in FIG. 11. However, one or more components, for example, transistor may be connected using silicided local interconnects.

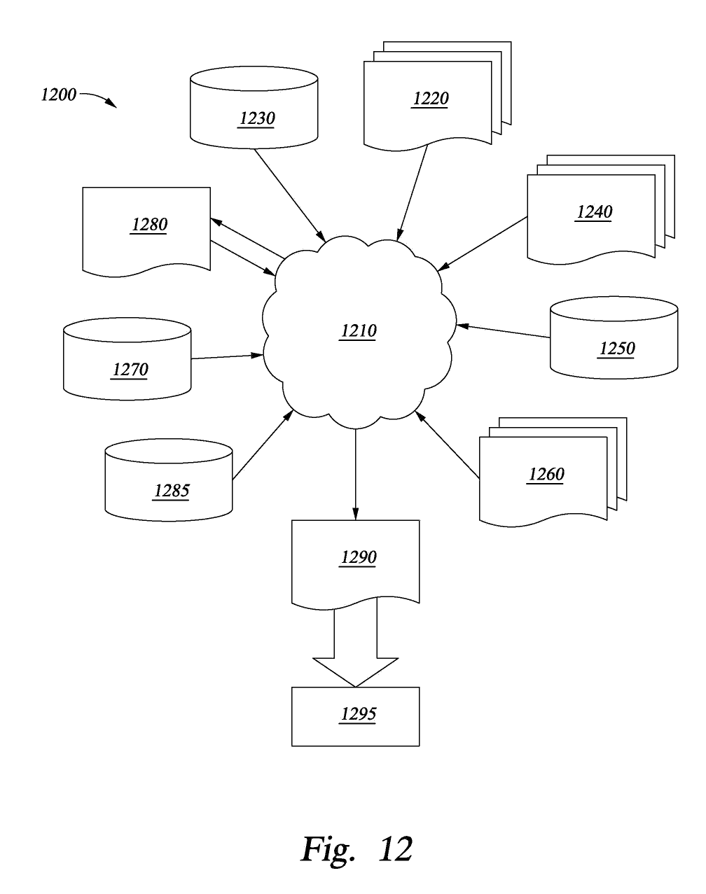

FIG. 12 shows a block diagram of an example design flow 1200. Design flow 1200 may vary depending on the type of IC being designed. For example, a design flow 1200 for building an application specific IC (ASIC) may differ from a design flow 1200 for designing a standard component. Design structure 1220 is preferably an input to a design process 1210 and may come from an IP provider, a core developer, or other design company or may be generated by the operator of the design flow, or from other sources. Design structure 1220 comprises the circuits described above and shown in FIGS. 2-6 and 8-11 in the form of schematics or HDL, a hardware-description language (e.g., Verilog, VHDL, C, etc.). Design structure 1220 may be contained on one or more machine readable medium. For example, design structure 1220 may be a text file or a graphical representation of circuit 1200. Design process 1210 preferably synthesizes (or translates) the circuits described above in and shown in FIGS. 2-6 and 8-11 into a netlist 1280, where netlist 1280 is, for example, a list of wires, transistors, logic gates, control circuits, I/O, models, etc. that describes the connections to other elements and circuits in an integrated circuit design and recorded on at least one of machine readable medium. This may be an iterative process in which netlist 1280 is resynthesized one or more times depending on design specifications and parameters for the circuit.

Design process 1210 may include using a variety of inputs; for example, inputs from library elements 1230 which may house a set of commonly used elements, circuits, and devices, including models, layouts, and symbolic representations, for a given manufacturing technology (e.g., different technology nodes, 32 nm, 45 nm, 90 nm, etc.), design specifications 1240, characterization data 1250, verification data 1260, design rules 1270, and test data files 1285 (which may include test patterns and other testing information). Design process 1210 may further include, for example, standard circuit design processes such as timing analysis, verification, design rule checking, place and route operations, etc. One of ordinary skill in the art of integrated circuit design can appreciate the extent of possible electronic design automation tools and applications used in design process 1210 without deviating from the scope and spirit of the invention. The design structure of the invention is not limited to any specific design flow.

Design process 1210 preferably translates an embodiment of the invention as described above and shown in FIGS. 2-6 and 8-11, for example, along with any additional integrated circuit design or data (if applicable), into a second design structure 1290. Design structure 1290 resides on a storage medium in a data format used for the exchange of layout data of integrated circuits (e.g., information stored in a GDSII (GDS2), GL1, OASIS, or any other suitable format for storing such design structures). Design structure 1290 may comprise information such as, for example, test data files, design content files, manufacturing data, layout parameters, wires, levels of metal, vias, shapes, data for routing through the manufacturing line, and any other data required by a semiconductor manufacturer to produce an embodiment of the invention as described above and shown in FIGS. 2-6 and 8-11, for example. Design structure 1290 may then proceed to a stage 1295 where, for example, design structure 1290: proceeds to tape-out, is released to manufacturing, is released to a mask house, is sent to another design house, is sent back to the customer, etc.

### Conclusion

By providing silicided local interconnect structures, embodiments of the invention allow the formation of smaller and cheaper circuits. Furthermore, because the need for metal contacts and metal layers is obviated, circuit complexity is also reduced.

While the foregoing is directed to embodiments of the present invention, other and further embodiments of the invention may be devised without departing from the basic scope thereof, and the scope thereof is determined by the claims that follow.

What is claimed is:

1. A design structure embodied in a machine readable storage medium for at least one of designing, manufacturing, and testing a design, the design structure comprising:
a transistor, comprising:
a source region;
a drain region; and
a channel region coupled with the source region and the drain region, wherein at least one of the source region and the drain region is a semiconductor fin structure, and wherein at least a portion of the fin structure comprises a silicide material, the portion of the fin structure comprising the silicide material being configured to electrically couple one of the respective source region and drain region of the transistor with an associated circuit component of an electric circuit.

2. The design structure of claim 1, wherein the design structure comprises a netlist, which describes the transistor.

3. The design structure of claim 1, wherein the design structure resides on the storage medium as a data format used for the exchange of layout data of integrated circuits.

4. The design structure of claim 1, wherein the design structure includes at least one of test data files, characterization data, verification data, or design specifications.

5. A design structure embodied in a machine readable storage medium for at least one of designing, manufacturing, and testing a design, the design structure comprising:
an electrical circuit, comprising:
a first circuit component;
a second circuit component; and
a fin structure coupled with the first circuit component and the second circuit component, wherein at least a portion of the semiconductor fin structure comprises a silicide material, the portion of the semiconductor fin structure comprising the silicide material being configured to electrically connect the first circuit component to the second circuit component.

6. The design structure of claim 5, wherein the design structure comprises a netlist, which describes the electrical circuit.

7. The design structure of claim 5, wherein the design structure resides on the storage medium as a data format used for the exchange of layout data of integrated circuits.

8. The design structure of claim 5, wherein the design structure includes at least one of test data files, characterization data, verification data, or design specifications.
